(19) United States
(12) Patent Application Publication
(10) Pub. No.: US 2026/0153405 A1
(43) Pub. Date: Jun. 4, 2026

(54) OPTICAL COATING FOR ELIMINATING GHOST IMAGES IN OPTICAL METROLOGY TOOLS

(71) Applicant: Applied Materials, Inc., Santa Clara, CA (US)

(72) Inventors: Yongan XU, Santa Clara, CA (US); Yangyang SUN, San Jose, CA (US); Jinxin FU, Fremont, CA (US)

(21) Appl. No.: 19/123,123

(22) PCT Filed: Oct. 27, 2023
(86) PCT No.: PCT/US2023/036153

§ 371 Date: Apr. 22, 2025

Related U.S. Application Data
(60) Provisional application No. 63/381,311, filed on Oct. 28, 2022.

(51) Int. Cl. G03F 1/84; G03F 7/00

(52) U.S. Cl. CPC G01M 11/30; G02B 1/11; G02B 27/0101; G03F 1/46; G03F 7/706849; G03F 7/70958

(57) ABSTRACT

The present disclosure relates to metrology measurement systems and related methods. In one or more embodiments a measurement system is provided. The measurement system includes a stage operable to retain an object and a light engine disposed above the stage. The light engine includes a light source directed towards the object, a first lens operable to collimate or focus a light from the light source, a reticle tray disposed between the light source and the first lens, and a reticle coupled to a reticle tray. The reticle includes a pattern and an anti-reflective coating disposed on the reticle. The coating is aligned with the pattern.

### BACKGROUND

### Field

Embodiments of the present disclosure generally relate to optical devices for augmented, virtual, and mixed reality. More specifically, embodiments described herein provide for metrology methods and systems.

### Description of the Related Art

Virtual reality is generally considered to be a computer generated simulated environment in which a user has an apparent physical presence. A virtual reality experience can be generated in 3D and viewed with a head-mounted display (HMD), such as glasses or other wearable display devices that have near-eye display panels as lenses to display a virtual reality environment that replaces an actual environment.

Augmented reality, however, enables an experience in which a user can still see through the display lenses of the glasses or other HMD device to view the surrounding environment, yet also see images of virtual objects that are generated for display and appear as part of the environment. Augmented reality can include any type of input, such as audio and haptic inputs, as well as virtual images, graphics, and video that enhances or augments the environment that the user experiences. As an emerging technology, there are many challenges and design constraints with augmented reality.

One such challenge is measuring optical devices for image quality standards. To ensure that image quality standards are met, metrology metrics of the fabricated optical devices must be obtained. However, existing measurement systems lack a desired field of view and suffer from ghost images, also commonly referred to as “ghosting.” Accordingly, what is needed in the art is a measurement system and methods of using the measurement system with an improved field of view and a decreased occurrence of ghost images.

### SUMMARY

The present disclosure relates to metrology measurement systems and related methods. In one or more embodiments a measurement system is provided. The measurement system includes a stage operable to retain an object and a light engine disposed above the stage. The light engine includes a light source directed towards the object, a first lens operable to collimate or focus a light from the light source, a reticle tray disposed between the light source and the first lens, and a reticle coupled to a reticle tray. The reticle includes a pattern and an anti-reflective coating disposed on the reticle. The coating is aligned with the pattern.

In one or more embodiments a reticle is provided. The reticle includes a pattern and an anti-reflective coating disposed on the pattern, the coating being opaque.

In one or more embodiments a method is provided. The method includes projecting a beam from a light engine toward an optical device. The light engine is disposed in a measurement system. The method also includes passing the beam through a reticle toward an optical device where the beam undergoes total internal reflection within the optical device. The method also includes absorbing reflected light with a coating disposed on a pattern of the reticle, detecting one or more images of the beam when the beam is outcoupled to a detector, and processing the image to extract a metrology metric.

### BRIEF DESCRIPTION OF THE DRAWINGS

So that the manner in which the above recited features of the present disclosure can be understood in detail, a more particular description of the disclosure, briefly summarized above, may be had by reference to embodiments, some of which are illustrated in the appended drawings. It is to be noted, however, that the appended drawings illustrate only exemplary embodiments and are therefore not to be considered limiting of its scope, and may admit to other equally effective embodiments.

FIG. 1A is a perspective, frontal view of a substrate according to embodiments described herein.

FIG. 1B is a perspective, frontal view of an optical device according to embodiments described herein.

FIG. 2 is a schematic, cross-sectional view of a measurement system according to embodiments described herein.

FIG. 3 is a schematic view of a configuration of a light engine and detector within the body of the measurement system of FIG. 2 according to embodiments described herein.

FIG. 4 is a schematic view schematic view of the reticle tray of the measurement system according to embodiments described herein.

FIG. 5 is a flow diagram of a method of optical device metrology according to embodiments described herein.

To facilitate understanding, identical reference numerals have been used, where possible, to designate identical elements that are common to the figures. It is contemplated that elements and features of one embodiment may be beneficially incorporated in other embodiments without further recitation.

### DETAILED DESCRIPTION

Embodiments of the present disclosure generally relate to optical devices for augmented, virtual, and mixed reality. More specifically, embodiments described herein provide for metrology methods and systems. A metrology method and system are shown and described herein.

The techniques described herein include using a light engine to project a pattern with a light from the light engine. The projected pattern is received by an optical device and undergoes total internal reflection through the optical device, which is outcoupled to a sensor within a reflection detector. One or more images of the pattern are detected by the reflection detector. The techniques further include processing the image to extract metrology metrics.

As described above, one challenge encountered when measuring optical devices for image quality standards is the presence of ghost images. One source of ghost images is the reflection of light from the material used to form a pattern on a reticle. For example, reticles commonly implement a pattern that is formed of a reflective material, such as a metallic material (e.g., chrome). However, when such reticles are implemented to perform metrology, light may unintentionally be reflected off of an object being measured (e.g., a waveguide or other optical device) and back towards the reticle. The reflected light may then reflect off of the pattern disposed on the reticle and back towards the object being measured, resulting in the object receiving a ghost image of the pattern disposed on the reticle.

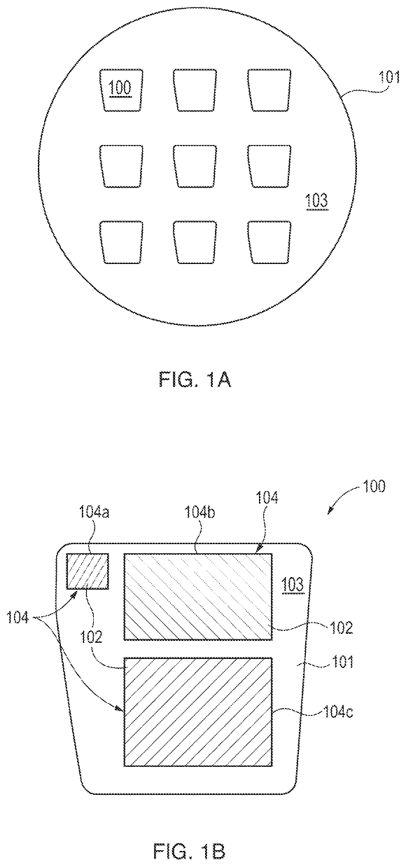

Accordingly, in various embodiments, a coating may be disposed on the reticle, such as by aligning and/or disposing the coating on the pattern, in order to reduce an amount of light reflected by the pattern. Such embodiments are described in further detail in conjunction with FIGS. 1A-5.

FIG. 1A is a perspective, frontal view of a substrate 101 according to embodiments described herein. The substrate includes a plurality of optical devices 100 disposed on a surface 103 of the substrate 101. In some embodiments, which can be combined with other embodiments described herein, the optical devices 100 are waveguide combiners utilized for virtual, augmented, or mixed reality. In some embodiments, which can be combined with other embodiments described herein, the optical devices 100 are flat optical devices, such as metasurfaces.

The substrate 101 can be any substrate used in the art, and can be either opaque or transparent to a chosen laser wavelength depending on the use of the substrate 101. The substrate 101 includes, but is not limited to, silicon (Si), silicon dioxide (SiO₂), fused silica, quartz, silicon carbide (SiC), germanium (Ge), silicon germanium (SiGe), indium phosphide (InP), gallium arsenide (GaAs), gallium nitride (GaN), silicon nitride (SIN), or sapphire containing materials. Additionally, the substrate 101 may have varying shapes, thicknesses, and diameters. For example, the substrate 101 may have a diameter of about 150 mm to about 300 mm. The substrate 101 may have a circular, rectangular, or square shape. The substrate 101 may have a thickness of between about 300 μm to about 1 mm. Although only nine optical devices 100 are shown on the substrate 101, any number of optical devices 100 may be disposed on the surface 103 of the substrate 101.

FIG. 1B is a perspective, frontal view of an optical device 100. It is to be understood that the optical devices 100 described herein are exemplary optical devices and the other optical devices may be used with or modified to accomplish aspects of the present disclosure. The optical device 100 includes a plurality of optical device structures 102 disposed on a surface 103 of a substrate 101. The optical device structures 102 may be nanostructures having sub-micron dimensions, e.g., nano-sized dimensions. Regions of the optical device structures 102 correspond to one or more gratings 104, such as a first grating 104a, a second grating 104b, and a third grating 104c. In one embodiment, which can be combined with other embodiments described herein, the optical device 100 includes at least the first grating 104a corresponding to an input coupling grating and the third grating 104c corresponding to an output coupling grating. In another embodiment, which can be combined with other embodiments described herein, the optical device 100 also includes the second grating 104b corresponding to an intermediate grating. The optical device structures 102 may be angled or binary. The optical device structures 102 may have other cross-sections including, but not limited to, circular, triangular, elliptical, regular polygonal, irregular polygonal, and/or irregular shaped cross-sections.

In operation, the first grating 104a receives incident beams of light having an intensity from a light engine. In one embodiment, which can be combined with other embodiments described herein, the light engine is a microdisplay. The incident beams are split by the optical device structures 102 into T1 beams that have all of the intensity of the incident beams in order to direct a virtual image to the intermediate grating (if utilized) or to the third grating 104c. In one embodiment, which can be combined with other embodiments described herein, the T1 beams undergo total-internal-reflection (TIR) through the optical device 100 until the T1 beams come in contact with the optical device structures 102 of the intermediate grating. The optical device structures 102 of the intermediate grating diffract the T1 beams to T−1 beams that undergo TIR through the optical device 100 to the optical device structures 102 of the third grating 104c. The optical device structures 102 of the third grating 104c outcouple the T1 beams to the user's eye. The T1 beams outcoupled to the user's eye display the virtual image produced from the light engine from the user's perspective and further increase the viewing angle from which the user can view the virtual image. In another embodiment, which can be combined with other embodiments described herein, the T1 beams undergo total-internal-reflection (TIR) through the optical device 100 until the T1 beams come in contact with the optical device structures 102 of the third grating 104c and are outcoupled to display the virtual image produced from the light engine.

To ensure that the optical devices 100 meet image quality standards, metrology metrics of the fabricated optical devices 100 must be obtained. The metrology metrics of each optical device 100 are tested to ensure that pre-determined values are achieved. Embodiments of the measurement system 200 described herein provide for the ability to obtain multiple metrology metrics with increased throughput. The metrology metrics include one or more of an angular uniformity metric, a contrast metric, a efficiency metric, a color uniformity metric, a modulation transfer function (MTF) metric, a field of view (FOV) metric, a ghost image metric, and an eye box metric.

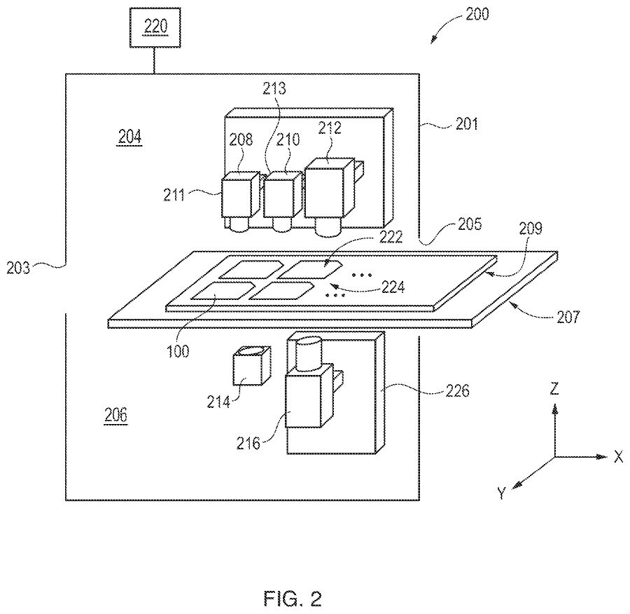

FIG. 2 is a schematic, cross-sectional view of a measurement system 200 according to embodiments described herein. The measurement system 200 includes a body 201 with a first opening 203 and a second opening 205 to allow a stage 207 to move therethrough. The stage 207 is operable to move in an X-direction, a Y-direction, and a Z-direction in the body 201 of the measurement system 200. The stage 207 includes a tray 209 operable to retain the optical devices 100 (as shown herein) or one or more substrates 101 with the optical devices 100 disposed thereon.

The measurement system 200 is operable to obtain one or more metrology metrics including one or more of the angular uniformity metric, the contrast metric, the efficiency metric, the color uniformity metric, the MTF metric, the FOV metric, the ghost image metric, or the eye box metric. The stage 207 and the tray 209 may be transparent such that the metrology metrics obtained by the measurement system 200 are not impacted by the translucence of the stage 207 or the tray 209. The measurement system 200 is in communication with a controller 220. The controller 220 is operable to facilitate operation of the measurement system 200.

The measurement system 200 includes an upper portion 204 oriented toward a top side 222 of the optical devices 100 and a lower portion 206 oriented toward a bottom side 224 of the optical device 100. The upper portion 204 of the measurement system 200 includes an alignment camera 208, a light engine 210, and a reflection detector 212. The alignment camera 208 is operable to determine a position of the stage 207. The alignment camera 208 is also operable to determine a position of the optical devices 100 disposed on the stage 207. The alignment camera 208 includes an alignment camera body 211. The light engine 210 is operable to project light. For example, the light engine 210 is operable to illuminate a first grating 104a of the optical devices 100. The light engine 210 includes a light engine body 213. In one embodiment, which can be combined with other embodiments described herein, the light engine 210 projects a pattern to the first grating 104a. The reflection detector 212 detects outcoupled beams projected from a third grating 104c of the optical devices 100. The outcoupled beams may be emitted from the top side 222 or the bottom side 224 of the optical devices 100. The outcoupled beams may correspond to the pattern from the light engine 210. One or more images of the pattern are detected by the reflection detector 212. The one or more images of the pattern may be processed with the controller 220 to extract each metrology metric.

The lower portion 206 of the measurement system 200 includes a code reader 214 and a transmission detector 216. The code reader 214 and the transmission detector are positioned opposite the alignment camera 208, the light engine 210, and the reflection detector 212 on the other side of the stage 207. The code reader 214 is operable to read a code of the optical devices 100, such as a quick response (QR) code or barcode of an optical device 100. The code read by the code reader 214 may include identification information and/or instructions for obtaining the one or more metrology metrics of the optical devices 100. The transmission detector 216 detects outcoupled beams projected from the third grating 104c though the bottom side 224 of the optical devices 100. In one embodiment, which can be combined with other embodiments described herein, the transmission detector 216 is coupled to a transmission detector stage 226. The transmission detector stage 226 is operable to move the transmission detector 216 in an X-direction, a Y-direction, and a Z-direction. The transmission detector stage 226 is operable to adjust the position of the transmission detector 216 to enhance the detection of the outcoupled beams projected from the third grating 104c

In operation, the metrology metrics are obtained by illuminating the first grating 104a of an optical device 100 with the light engine 210. The light engine 210 projects a pattern to the one or more optical devices 100. The incoupled light undergoes TIR until the light is outcoupled (e.g., reflected or transmitted) out of the optical device 100. The pattern is captured by the reflection detector 212 as one or more images. The one or more images may correspond to red, green, and blue channels. The one or more images may also correspond to one or more different metrology metrics. In various embodiments, the one or more images are full-field images.

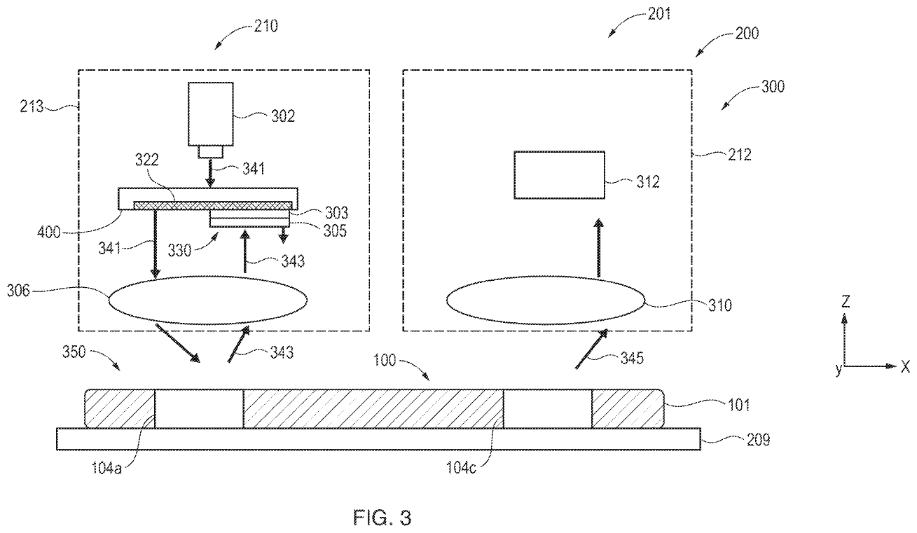

FIG. 3 is a schematic view of a configuration 300 of a light engine 210 and the reflection detector 212 within the body 201 of the measurement system 200 (FIG. 2) according to embodiments described herein. The light engine 210 includes a light source 302, a first lens 306, and a reticle tray 400. The reflection detector 212 includes a second lens 310 and a sensor 312. The light source 302, the first lens 306, the reticle tray 400, and the second lens 310 are disposed in the body 201.

The light source 302 is operable to project a first light beam 341. The first light beam 341 may be white light corresponding to a range of wavelengths. In one or more embodiments, which can be combined with other embodiments described herein, the light source 302 is a LED. In another embodiment, which can be combined with other embodiments described herein, the range of wavelengths is 390 nm to 750 nm corresponding to white light.

The reticle tray 400 is operable to move in one or more of an X-direction, a Y-direction, and a Z-direction. Therefore, the reticle tray 400 may be adjusted such that light is projected though a reticle 322. The reticle tray 400 is adjusted in the Z-direction to improve the quality of the pattern to be projected. For example, adjusting the reticle tray 400 in the Z-direction may change the angle and intensity of the light incident on the reticle 322. The reticle tray 400 is disposed between an object 350 and the light source 302. The object 350 may be the optical device 100 and/or an optical device substrate.

The first lens 306 is disposed between the reticle tray 400 and the object 350. The first lens 306 collimates or focuses the first light beam 341 towards the object 350. In one embodiment, which can be combined with other embodiments described herein, the first lens 306 is an eyepiece lens.

The optical device 100 is disposed on the tray 209. The optical device 100 includes the first grating 104a and the third grating 104c. The first grating 104a corresponds to an input coupling grating of the optical device 100. The third grating 104c corresponds to an output coupling grating of the optical device 100.

The second lens 310 is disposed between the third grating 104c and the sensor 312 of the reflection detector 212. The second lens 310 focuses light towards the sensor 312. The sensor 312 is used to measure attributes of the object 350.

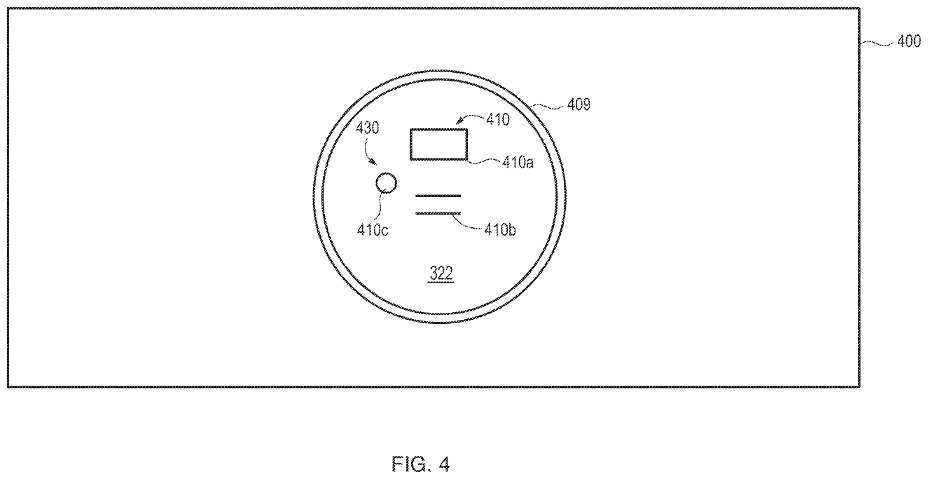

The reticle tray 400 includes the reticle 322. The reticle tray 400 may include one or more reticles 322. The reticle 322 includes one or more patterns (e.g., patterns 410 shown in FIG. 4), as described below in further detail. In one or more embodiments, the reticle 322 is a transparent substrate with a non-transparent pattern 410. In some embodiments, the pattern 410 of the reticle 322 includes a metallic material, such as chromium, aluminum, or silver. A coating 330 is further disposed on the reticle 322.

In various embodiments, the coating 330 is an anti-reflective coating. The coating 330 is disposed on one or more patterns 410 of the reticle 322. In some embodiments, the coating 330 is disposed on less than all of the reticle, such as by aligning the coating 330 with the pattern(s) 410. Further, in some embodiments, the coating 330 may be disposed on the pattern(s) 410.

In one or more embodiments, the coating 330 is a multilayer coating. For example, the coating 330 may include a first layer 303 and a second layer 305. While the coating 330 is shown as having a first layer 303 and a second layer 305, other embodiments are contemplated. In various embodiments, the coating 330 includes two or more layers. For example, the coating 330 may include a first layer 303, a second layer 305, and a third layer. The coating 330 has a thickness of about 10 nanometers to about 10 micrometers, such as about 50 nanometers to about 5 micrometers, such as about 100 nanometers to about 1 micrometer. In various embodiments, the first layer 303 and/or the second layer 305 comprise a metal material. The metal may include one or more of gold (Au), platinum (Pt), aluminum (Al), silver (Ag), chromium (Cr), and/or titanium (Ti). In various embodiments, the first layer 303 and/or the second layer 305 a dielectric layer. The dielectric layer may include one or more of silicon oxide (SiOx), titanium oxide (TiOx), niobium oxide (NbOx), zirconium oxide (ZrOx), tantalum oxide (TaOx), silicon nitride (SIN), magnesium fluoride (MgF₂), and/or silicon. In various embodiments, the coating 330 may be formed of alternating the metal layers and the dielectric layer as the first layer 303 and the second layer 305. In some embodiments, the coating 330 includes 3 of more layers that alternate between a metal layer and a dielectric layer, such as 4 or more layers (e.g., 2 metal layers interleaved with 2 dielectric layers), such as 6 or more layers (e.g., 3 metal layers interleaved with 3 dielectric layers).

In various embodiments, the coating 330 has a refractive index of less than 6. In some embodiments, the coating 330 has a refractive index of about 1 to about 4.2, such as a refractive index of about 1.2 to about 4.

In various embodiments, the coating 330 reduces an amount of reflected light 343 that is reflected off of the pattern(s) 410 of the reticle 322, back towards the optical device 100. For example, the coating 330 may include an opaque material that absorbs light and does not reflect the light back towards optical device 100. In some embodiments, the coating 330 material is selected based on the type of material used to form the patterns 410. For example, if the pattern 410 is formed by deposition of a metallic material on the reticle 322, then the coating 330 may be the oxide of the metallic material. In a specific example, when the pattern 410 includes chromium, the first layer 303 and/or second layer 305 of the coating 330 may include chromium oxide.

The coating 330 material is chosen such that when reflected light 343 travels through the coating 330 to the patterns 410, the reflected light 343 is absorbed by the coating 330 and is reduced to 20% or less. For example, if reflected light 343 enters to coating 330 at an intensity of 100%, then the reflected light 343 is reflected from the patterns 410 back through the coating 330 at about an intensity of 20% or less, such as about 15% or less, such as about 5% or less. By implementing alternating layers (e.g., alternating metal layers and dielectric layers) the reflected light 343 is more effectively absorbed by the coating 330 instead of being reflected back towards the optical device 100.

In some embodiments, which may be combined with other embodiments described herein, the first layer 303 includes the same metallic material as the pattern 410, and the second layer 305 is a dielectric layer.

As described above, when reflected light 343 is received by the optical device 100 and outcoupled from the third grating 104c, the reflected light 343 causes a ghost image (e.g., of a pattern 410) to be received by the sensor 312. As described in further detail below, implementing a coating 330 on the reticle 322 reduces the incidence of ghost images.

In operation, the light source 302 projects the first light beam 341 through the reticle 322 of the reticle tray 400 to produce a projected pattern 342 that corresponds to pattern 410 (FIG. 4). The projected pattern 342 is received by the first lens 306, which collimates or focuses the projected pattern 342 onto the object 350. In one or more embodiments, the object 350 is the optical device 100 of FIG. 1. For example, the first lens 306 may collimate the projected pattern 342, which is then received by the first grating 104a. The projected pattern 342 then undergoes TIR within the optical device 100 and is outcoupled from the third grating 104c as outcoupled light 345.

The outcoupled light 345 travels to the second lens 310. The second lens 310 focuses the outcoupled light 345 onto the sensor 312 of the reflection detector 212.

In various embodiments, a portion of the first light beam 341 is reflected back from the optical device 100 as reflected light 343. The reflected light 343 travels from the optical device 100 back through the first lens 306 and is absorbed by the coating 330, preventing the light from being reflected back towards the first grating 104a. Accordingly, the incidence of ghost images is reduced by the coating 330, improving the accuracy of measurements.

FIG. 4 is a schematic view of the reticle tray 400 of the measurement system 200 according to embodiments described herein. The reticle tray 400 includes one or more reticle apertures 409. The one or more reticles 322 are disposed in the reticle apertures 409. The reticle 322 may include one or more patterns 410 to be projected to the first grating 104a of the optical device 100. The reticle 322 includes a transparent region 430 where a coating 330 (FIG. 3) and/or a pattern 410 is not disposed.

As described above in conjunction with FIG. 3, the pattern(s) 410 may include one or more rectangular patterns 410a, line patterns 410b, circular patterns 410c, or any other shape(s) or combinations thereof. The pattern(s) 410 provide a reference of known size and shape, so that any changes to the patterns 410 as the projected pattern 342 (FIG. 3) travels through gratings of the optical device 100 can be detected.

In some embodiments, each of the patterns 410 of the reticle 322 may correspond to a different metrology metric to be determined by the measurement system 200. For example, one or more patterns 410 may be implemented to measure different types of geometric distortion.

In some embodiments, which can be combined with other embodiments described herein, a single pattern may be implemented to measure multiple metrology metrics. In some embodiments, which can be combined with other embodiments described herein, the metrology metrics may require more than one pattern to be used. Thus, one or more reticles 322 may be used to obtain different metrology metrics for the optical device 100. The reticle tray 400 is not limited to one reticle 322. In some embodiments, the reticle tray 400 is operable to retain multiple reticles 322, such as three or more reticles 322. For example, an array of the reticle 322 may be disposed on the reticle tray 400.

In some embodiments, the coating 330 is aligned with the pattern(s) 410 such that the coating 330 is disposed between the pattern(s) 410 and the object to be measured. By aligning the coating 330 with the pattern(s) 410, such that regions of the reticle 322 which are not covered by the pattern(s) 410 remain transparent, the first light beam 341 can pass through the reticle 322 to form a projected pattern, but reflected light 343 will either pass through the transparent regions 430 of the reticle 322 or be absorbed by the coating 330, reducing the incidence of reflections and ghost images.

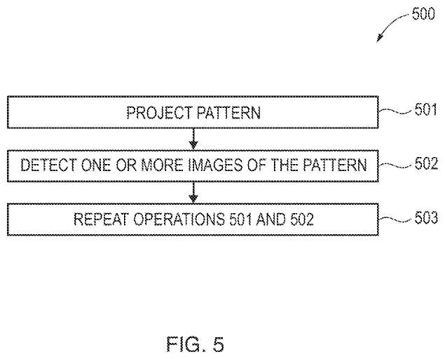

FIG. 5 is flow diagram of a method 500 of optical device metrology according to embodiments described herein. The method 500 may be utilized to project a pattern to a first grating 104a of an optical device 100. The method 500 may be utilized with the configurations 300 of the light engine 210. In one embodiment, which can be combined with other embodiments described herein, the light engine 210 is operable to be disposed on a rotation stage such that the light engine 210 may be rotated and/or tilted as desired during the method 500.

At operation 501, a pattern is projected. The pattern is projected via a light engine 210. As shown in FIG. 3, the first light beam 341 may be projected by the light source 302. The first light beam 341 may be directed to a reticle 322. The first light beam 341 passes through the reticle 322 and into the first lens 306 from the light source 302 to collimate the light. The first light beam 341 corresponds to a wavelength or a range of wavelengths.

In some embodiments, which can be combined with other embodiments described herein, as shown in FIG. 3, the reticle 322 is chosen based on one or more metrology metrics to be determined. The pattern corresponding to one of the patterns 410 is projected to a first grating 104a of an optical device 100. The pattern 410a, 410b, 410c may be directed to the first grating 104a through the first lens 306.

At operation 502, one or more images of the pattern are detected. The one or more images of the pattern are captured by the sensor 312. The pattern undergoes TIR until it is outcoupled (e.g., reflected or transmitted) and captured by the reflection detector 212 as the one or more images. The one or more images are processed to extract the metrology metrics. In various embodiments, the images are full-field images. The one or more images may be processed by a controller 220 (shown in FIG. 2). The controller 220 may be a remote controller 220 operable to receive the one or more images. The controller 220 may include a central processing unit (CPU) configured to process computer-executable instructions stored in memory. The computer-executable instructions may include algorithms configured to extract the metrology metrics. For example, the controller 220 is configured to perform embodiments of the method 500 described herein, such as processing the one or more images to determine values for the metrology metric corresponding to the respective pattern captured in the one or more images. One of skill in the art will appreciate that one or more elements of the controller 220 may be located remotely and accessed via a network.

At operation 503, the operation 501 and the operation 502 are repeated for subsequent reticles 322 and/or patterns 410 disposed thereon.

Benefits of the present disclosure include a reduction in ghost images detected by the incorporation of the coating on reflective surfaces of the reticle 322.

While the foregoing is directed to embodiments of the present disclosure, other embodiments of the disclosure may be devised without departing from the basic scope thereof, and the scope thereof is determined by the claims that follow.

What is claimed is:

1. A measurement system, comprising:
a stage operable to retain an object; and
a light engine disposed above the stage, the light engine including:
a light source directed towards the object;
a first lens operable to collimate or focus a light from the light source;
a reticle tray disposed between the light source and the first lens; and
a reticle coupled to a reticle tray, the reticle comprising:
a pattern; and
an anti-reflective coating disposed on the reticle and aligned with the pattern.

2. The measurement system of claim 1, wherein the coating comprises a multilayer coating.

3. The measurement system of claim 1, wherein the coating is configured to absorb light reflected from the object.

4. The measurement system of claim 1, wherein the coating is disposed between the pattern and the object.

5. The measurement system of claim 1, wherein the coating is opaque.

6. The measurement system of claim 1, wherein the object comprises one or more optical devices disposed on a substrate.

7. The measurement system of claim 6, wherein the one or more optical devices comprise a waveguide.

8. The measurement system of claim 1, wherein the pattern comprises a metal.

9. The measurement system of claim 8, wherein the coating comprises an oxide of the metal.

10. A reticle, comprising:
a pattern; and
an anti-reflective coating disposed on the pattern, the coating being opaque.

11. The reticle of claim 10, wherein the pattern comprises a metal.

12. The reticle of claim 11, wherein the anti-reflective coating comprises an oxide of the metal.

13. The reticle of claim 10, wherein the anti-reflective coating comprises a multilayer coating.

14. The reticle of claim 10, wherein the pattern and the anti-reflective coating are disposed on a first side of the reticle.

15. A method, comprising:
projecting a beam from a light engine toward an optical device, the light engine disposed in a measurement system;
passing the beam through a reticle toward an optical device, the beam undergoing total internal reflection within the optical device;
absorbing reflected light with a coating disposed on a pattern of the reticle;
detecting one or more images of the beam when the beam is outcoupled to a detector; and
processing the image to extract a metrology metric.

16. The method of claim 15, wherein the light engine comprises:
a body;
a light source disposed within the body;
a first lens operable to collimate or focus a light from the light source; and
a reticle tray disposed between the light source and the first lens, the reticle tray including the reticle.

17. The method of claim 15, wherein the coating is opaque.

18. The method of claim 15, wherein the coating is a multilayer coating.

19. The method of claim 15, wherein the pattern comprises a metal.

20. The method of claim 15, wherein the coating comprises an oxide.
